(19) United States
(12) Patent Application Publication
(10) Pub. No.: US 2026/0245629 A1
(43) Pub. Date: Aug. 20, 2026

(54) METHODS OF MEMORY, MEMORY, AND MEMORY SYSTEMS

(71) Applicant: Yangtze Memory Technologies Co., Ltd., Wuhan (CN)

(72) Inventors: Ke Ke, Wuhan (CN); Zhipeng Dong, Wuhan (CN); Jianjie Li, Wuhan (CN)

(21) Appl. No.: 19/236,360

(22) Filed: Jun. 12, 2025

(30) Foreign Application Priority Data
Feb. 18, 2025 (CN) 202510180486.X

(51) Int. Cl. G11C 16/26; G11C 16/04

(52) U.S. Cl. CPC G11C 16/26; G11C 16/0483

(57) ABSTRACT

The present disclosure provides an operation method of a memory, a memory, and a memory system, and relates to the field of memory technology. The memory includes a memory array and a peripheral circuit. The memory array includes a plurality of memory cells. The method includes: receiving, by the peripheral circuit, a read command; performing a read operation on data stored in a target memory cell in the plurality of memory cells for k times in response to the read command to obtain k read data of the data in the target memory cell, wherein k is an odd number greater than or equal to 2; and determining a read result of the data in the target memory cell based on the k read data.

### CROSS-REFERENCE TO RELATED APPLICATIONS

This application claims priority to and the benefit of Chinese Patent Application 202510180486.X, filed on Feb. 18, 2025, which is hereby incorporated by reference in its entirety.

### FIELD OF TECHNOLOGY

The present disclosure relates to the field of memory technology, and in particular to methods of memory, memory, and memory systems.

### BACKGROUND

Flash memory is a widely used non-volatile memory that can be electrically erased and reprogrammed. Flash memory comprises NOR flash memory and NAND flash memory. The threshold voltage of the memory cells in the flash memory may be changed to a desired level to perform read, program, and erase operations. For NAND flash memory, an erase operation may be performed on a block level, and a program operation or a read operation may be performed on a page level.

### BRIEF DESCRIPTION OF THE DRAWINGS

FIG. 1 illustrates a block diagram of an example system having a memory according to an implementation of the present disclosure.

FIG. 2 illustrates a block diagram of a memory system.

FIG. 3 illustrates a block diagram of another memory system.

FIG. 4 is a schematic circuit diagram of a memory comprising a peripheral circuit, according to an implementation of the present disclosure.

FIG. 5 is a schematic diagram of a peripheral circuit according to an implementation of the present disclosure.

FIG. 6 is a flowchart illustrating an operation method of a memory according to an example implementation.

FIG. 7 is a schematic diagram illustrating a Gray code diagram of a TLC according to an example implementation.

FIG. 8 is a schematic diagram illustrating a Gray code diagram of a QLC according to an example implementation.

FIG. 9 is a schematic electrical diagram illustrating a memory string of a sense process according to an example implementation.

FIG. 10 is a schematic diagram illustrating a WL waveform of a TLC forward read according to an example implementation.

FIG. 11 is a schematic diagram illustrating a change of potential of a sense operation SO node according to an example implementation.

FIG. 12 is a schematic diagram illustrating a change of potential of an SO node corresponding to a memory cell that is turned on and turned off in a sense operation according to an example implementation.

FIG. 13 is a circuit block diagram illustrating a page buffer according to an example implementation.

FIG. 14 is a schematic diagram illustrating a threshold voltage distribution of 4.5 LC according to an example implementation.

### DETAILED DESCRIPTION

Example implementations will now be described more fully with reference to the drawings. However, the example implementations can be implemented in a variety of forms and should not be construed as limited to the implementations set forth herein; rather, these implementations are provided so that the present disclosure will be more comprehensive and complete and the concepts of the example implementations are fully conveyed to those skilled in the art. The drawings are merely schematic illustrations of the present disclosure and are not necessarily drawn to scale. Like reference numbers in the drawings refer to the same or similar parts, and thus repeated description thereof will be omitted.

Furthermore, the described features, structures, or characteristics may be incorporated in one or more implementations in any suitable manner. In the following description, numerous specific details are provided to give a thorough understanding of implementations of the present disclosure. However, those skilled in the art will appreciate that the technical solutions of the present disclosure may be practiced with one or more of the specific details omitted, or other methods, devices, steps, etc. may be employed. In other instances, well-known structures, methods, devices, implementations, or operations are not shown or described in detail to avoid obscuring aspects of the present disclosure.

Furthermore, the terms “first”, “second” and the like are for descriptive purposes only and are not to be construed as indicating or implying relative importance or implicitly indicating the number of indicated technical features. Thus, features defining with “first”, “second” may explicitly or implicitly comprise one or more of the features. In the description of the present disclosure, the meaning of “a plurality of” is at least two, for example, two, three, etc., unless specifically defined otherwise. The symbol “/” indicates a “or” relationship between the associated objects before “/” and after “/”.

In the present disclosure, unless otherwise specified and limited, terms such as “connection” should be understood broadly, for example, may be electrical connections or communication with each other; may be direct connection or indirect connection through an intermediate medium. For those skilled in the art, the specific meaning of the above terms in the present disclosure may be understood according to specific situations.

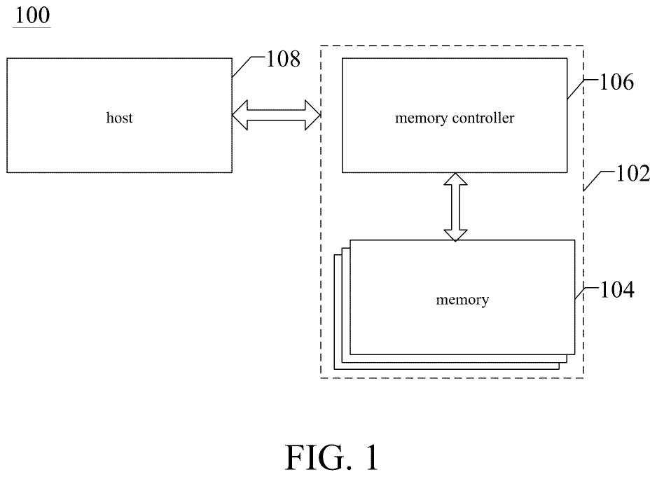

FIG. 1 illustrates a block diagram of an example system having a memory according to an implementation of the present disclosure. The system 100 may be a mobile phone, a desktop computer, a laptop, a tablet, a vehicle computer, a game console, a printer, a pointing device, a wearable electronic device, a smart sensor, a virtual reality device, an augmented reality device, or any other suitable electronic device having memory therein.

As shown in FIG. 1, the system 100 may comprise a host 108 and a memory system 102. The memory system 102 has one or more memories 104 and a memory controller 106. The host 108 may be a processor of an electronic device (e.g., a central processing unit (CPU)) or a system-on-a-chip (SoC) (e.g., an application processor). The host 108 may be configured to send or receive data to or from the memory 104.

The memory 104 may be any memory in the present disclosure, for example, a non-volatile memory. The non-volatile memory may be a NAND flash memory (e.g., a three-dimensional (3D) NAND flash memory).

In some implementations, the memory controller 106 is coupled to the memory 104 and the host 108 and is configured to control the memory 104. The memory controller 106 may manage data stored in the memory 104 and communicate with the host 108.

In some implementations, the memory controller 106 is configured to send a command (comprising a read command) to the memory 104, so that the memory 104 executes the operation method of the memory according to the implementations of the present disclosure.

In some implementations, the memory controller 106 is designed to operate in a low duty cycle environment, such as a secure digital (SD) card, a compact flash memory (CF) card, a universal serial bus (USB) flash drive, or other medium for use in electronic devices such as personal computers, digital cameras, mobile phones, and the like.

In some implementations, the memory controller 106 is designed to operate in a high duty cycle environment, such as a solid state drive (SSD) or an embedded multimedia card (eMMC), which may be used as a data store for mobile devices such as smartphones, tablets, laptops, and the like, as well as enterprise memory arrays. The memory controller 106 may be configured to send commands to the memory 104 to cause the memory 104 to perform operations, such as read, erase, and program operations.

The memory controller 106 may also be configured to manage various functions regarding data stored in or to be stored in the memory 104, comprising, but not limited to, bad block management, garbage collection, logical-to-physical address translation, wear leveling, and the like.

In some implementations, the memory controller 106 is further configured to process error correction codes (ECC) regarding data read from or written to the memory 104. Memory controller 106 may also perform any other suitable functions, such as formatting memory 104. The memory controller 106 may communicate with an external device (e.g., host 108) according to a particular communication protocol. For example, the memory controller 106 may communicate with the external device through at least one of a variety of interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like.

The memory controller 106 and one or more of the memories 104 may be integrated into various types of storage devices, e.g., comprised in the same package (e.g., a Universal Flash Memory (UFS) package or an eMMC package). That is, the memory system 102 may be implemented and packaged into different types of terminal electronics.

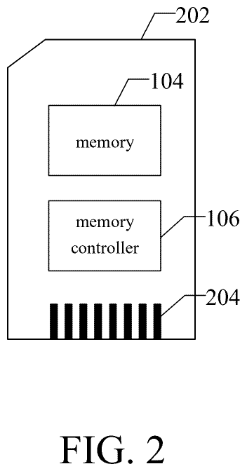

FIG. 2 illustrates a block diagram of a memory system. As shown in FIG. 2, the memory controller 106 and the single memory 104 may be integrated into the memory card 202. The memory card 202 may comprise a PC card (also referred to as a PCMCIA card, a personal computer memory card international association card), a CF card, a smart media (SM) card, a memory stick, a multi-media card (e.g., an MMC card, a reduced-size MMC (RS-MMC) card, an MMCmicro card, etc.), an SD card (e.g., an SD card, a miniSD card, a microSD card, an secure digital high capacity (SDHC) card, etc.), a UFS card, or the like. The memory card 202 may also comprise a memory card connector 204 that couples the memory card 202 with a host (e.g., the host 108 in FIG. 1).

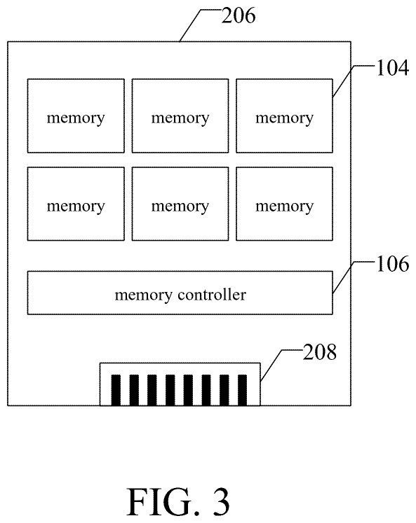

FIG. 3 illustrates a block diagram of another memory system. As shown in FIG. 3, the memory controller 106 and the plurality of memories 104 may be integrated into the SSD 206. SSD 206 may also comprise an SSD connector 208 that couples the SSD 206 with a host (e.g., the host 108 in FIG. 1). In some implementations, at least one of the storage capacity or operating speed of the SSD 206 is greater than at least one of the storage capacity or operating speed of the memory card 202.

An implementation of the present disclosure provides a memory system, comprising the memory according to any one of the implementations of the present disclosure and a memory controller coupled to the memory. The memory is configured to receive a read command from the memory controller to perform an operation method of a memory according to any one of the implementations of the present disclosure; and the memory controller is configured to receive a read result of the data in a target memory cell in a memory from the memory.

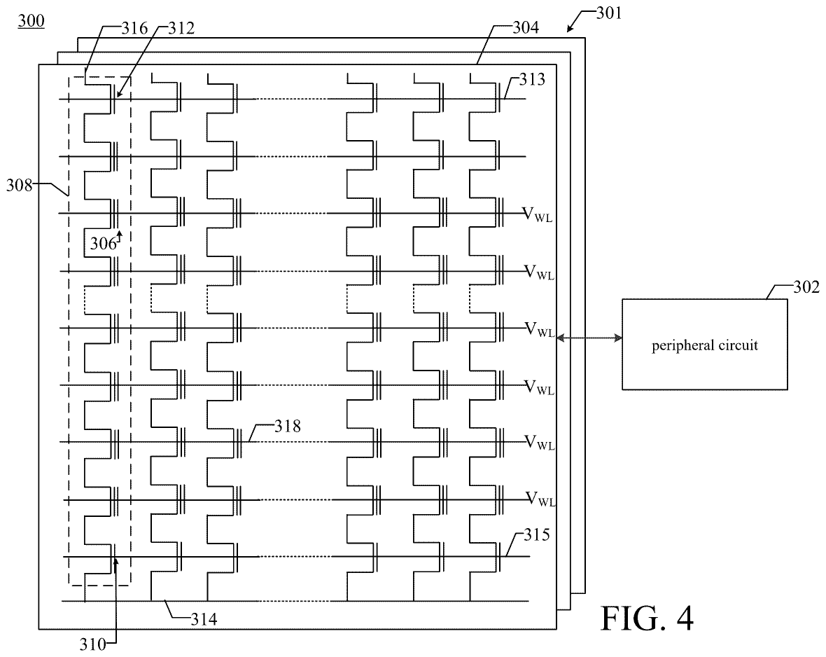

FIG. 4 is a schematic circuit diagram of a memory 300 comprising a peripheral circuit, according to an implementation of the present disclosure. Memory 300 may be an implementation of memory 104 in FIG. 1. The memory 300 may comprise a memory array 301 and peripheral circuit 302 coupled to the memory array 301. The memory array 301 may be a NAND flash memory array, that is, the memory herein may be referred to as a NAND memory. The memory cells 306 are provided in the form of an array of memory strings 308 of the NAND flash memory, with each memory string 308 extending vertically above a substrate (not shown).

In some implementations, the peripheral circuit 302 is configured to perform the operation method according to the implementations of the present disclosure. It may be understood that the peripheral circuit 302 may be configured to execute the operation method according to the implementations of the present disclosure according to an instruction (for example, a read command) received from the memory controller 106.

In some implementations, each memory string 308 comprises a plurality of memory cells 306 coupled in series and stacked vertically. Each memory cell 306 may maintain a continuous analog value, e.g., voltage or charge, depending on the number of electrons captured within the area of the memory cell 306. Each memory cell 306 may be a floating gate type memory cell comprising a floating gate transistor, or a charge trapping type memory cell comprising a charge trapping transistor.

In some implementations, each memory cell 306 may store 1 bit of data or 2 bits of data or more bits of data, that is, may be a Single-Level Cell (SLC) type, a Multi-Level Cell (MLC) type, a Triple-Level Cell (TLC) type, a Quad-Level Cell (QLC) type, or a higher level type. M (M is a real number greater than or equal to 1) level cell may have 24 states (e.g., one state corresponds to one threshold voltage distribution interval), and thus may store M bits of data. The SLC type memory cell may have 2 states, and thus may store 1 bit of data; the MLC type memory cell may have 4 states, and thus may store 2 bits of data; the TLC type memory cell may have 8 states, and thus may store 3 bits of data; the QLC type memory cell may have 16 states, and thus may store 4 bits of data; when M=4.5, one memory cell may store 4.5 bits of data, and have 24 states, and so on. The 2^{M} states can comprise one erased state and 2^{M}−1 programmed states/memory states. The NAND flash memory of M-level cell type may perform at least one of a program or read operation on data page by page in a unit of page. During a program operation, the NAND flash memory of M-level cell type is programmed to have 24 states, and when a memory cell is programmed to a target state in the 24 states, it is referred to as in a target program state/target memory state.

As shown in FIG. 4, each memory string 308 may comprise a source select gate (SSG) 310 at its source terminal and a drain select gate (DSG) 312 at its drain terminal. The SSG 310 and the DSG 312 may be configured to activate a selected memory string 308 (referred to as a target memory string) during read and program operations.

In some implementations, the sources of the memory strings 308 in the same block 304 are coupled through the same source line (SL) 314 (e.g., a common SL). For example, all of the memory strings 308 in the same block 304 have an array common source (ACS). As shown in FIG. 4, the memory strings 308 may be organized into a plurality of blocks 304, each of which may have a common source line 314 (e.g., coupled to ground). In some implementations, each block 304 is a basic unit of data for an erase operation, e.g., all of the memory cells 306 on the same block 304 are erased simultaneously.

In some implementations, the transistor of the DSG 312 of each memory string 308 is coupled to a respective bit line (BL) 316 from which data may be read or written via an output bus (not shown). Each memory string 308 may be configured to be selected or deselected by at least one of: applying a select voltage (e.g., higher than a threshold voltage of a transistor having the DSG 312) or a deselect voltage (e.g., OV) to a respective DSG 312 via one or more DSG lines 313; or applying a select voltage (e.g., higher than a threshold voltage of a transistor having the SSG 310) or a deselect voltage (e.g., OV) to respective SSGs 310 via one or more SSG lines 315.

As shown in FIG. 4, the memory cells 306 of the memory string 308 may be coupled through a word line (WL) 318, which selects which row of memory cells 306 are affected by read and program operations. Peripheral circuit 302 may be coupled to the memory array 301 through bit lines 316, word lines 318, source lines 314, SSG lines 315, and DSG lines 313. The peripheral circuit 302 may comprise any suitable analog, digital, and mixed-signal circuits for facilitating operation of the memory array 301 by applying at least one of a voltage signal or a current signal to and sensing at least one of a voltage signal or a current signal from each of the memory cells that are targeted (referred to as a target memory cell) via the bit lines 316, word lines 318, source lines 314, SSG lines 315, and DSG lines 313. The peripheral circuits may comprise various types of peripheral circuits formed using metal-oxide-semiconductor (MOS) technology.

An implementation of the present disclosure provides a memory, comprising: a memory array comprising a plurality of memory cells; a plurality of word lines respectively coupled to rows of the memory array; a plurality of bit lines respectively coupled to memory strings of the memory array; and a peripheral circuit coupled to the memory array through the word lines and the bit lines and configured to: receive a read command; perform read operations for k times on data stored in a target memory cell in the plurality of memory cells in response to the read command, to obtain k read data of the data in the target memory cell, where k is an odd number greater than or equal to 3; and determine a read result of the data in the target memory cell according to the k read data.

The target memory cell in the implementations of the present disclosure may be any memory cell in the memory. In the implementation of the present disclosure, the peripheral circuit continuously reads the same target memory cell for k times, and then determines the read result of the target memory cell according to the k read data read by k times, so that the reading accuracy of the target memory cell can be improved.

In an example implementation, a word line coupled to the target memory cell is a target word line; the data stored in the target memory cell comprises M bits, where M is a real number greater than 1. The peripheral circuit comprises a control logic circuit and a plurality of page buffers respectively coupled to the plurality of bit lines. The control logic circuit is configured to apply a m-th read voltage to the target word line for k times in response to the read command, to perform the read operation on an m-th bit data in M bits of data stored in the target memory cell for k times, to obtain k read data of the m-th bit data stored in the target memory cell, where m is a real number greater than or equal to 1 and less than or equal to M. The page buffer coupled to the target bit line comprises a latch circuit and a logic operation circuit, and is configured to: determine, by the latch circuit and the logic operation circuit, the read result of the m-th bit data in the M bits of data stored in the target memory cell according to the k read data of the m-th bit data.

In the implementation of the present disclosure, when M bits are stored in the same target memory cell, the peripheral circuit reads bit by bit, for example, reads the first bit in the target memory cell consecutively for k times to obtain k read data of the first bit, stores the k read data of the first bit by using the latch circuit in the page buffer coupled to the target bit line, and then processes the k read data of the first bit through the logic operation circuit in the page buffer to determine the read result of the first bit of the target memory cell. Thereafter, the peripheral circuit reads the second bit in the target memory cell consecutively for k times to obtain k read data of the second bit, stores the k read data of the second bit by using the latch circuit in the page buffer coupled to the target bit line, and then processes the k read data of the second bit through the logic operation circuit in the page buffer to determine the read result of the second bit of the target memory cell. This process is repeated until the read result of the M-th bit in the target memory cell is read.

In an example implementation, the peripheral circuit further comprises: a voltage generator configured to: generate the m-th read voltage for k times under the control of the control logic circuit, and sequentially apply the m-th read voltage to the target word line for k times.

In the implementation of the present disclosure, when the m-th bit data in M bits of data stored in the target memory cell is read consecutively for k times, the m-th read voltages are sequentially applied to the target word lines connected to the target memory cell for k times in the k consecutive read processes. The m-th read voltage refers to a read voltage configured to read the m-th bit data in the target memory cell.

In an example implementation, when M=4.5, the voltage generator is configured to generate 23 different read voltages under the control of the control logic circuit, and the m-th read voltage applied to the target word line comprises at least two different read voltages of the 23 different read voltages.

When M=4.5, the target memory cell has a total of 24 states, comprising 23 memory states and 1 erase state. To distinguish the 24 states, the voltage generator is configured to generate 23 different read voltages under the control of the control logic circuit for distinguishing between the 23 memory states and the 1 erase state. In the implementation of the present disclosure, when distinguishing among different memory states, the m-th read voltage applied to the target word line comprises at least two different read voltages of 22 different read voltages. The specific values of the at least two different read voltages may be set according to actual needs, which is not limited in the present disclosure. It should be noted that, although an implementation in which M=4.5, the target memory cell comprises 24 states, 23 different read voltages are generated to distinguish the 24 states is taken as an example to illustrate, the present disclosure is not limited thereto. In other implementations, when M=4.5, the 4.5-bit NAND may also have other numbers of states, and the number of generated read voltages matches the number of states of the 4.5-bit NAND.

In the implementations of the present disclosure, the HDD (Hard Disk Drive/Hard Disk) may be replaced with a NAND flash memory of M-level cell type, so as to improve storage capacity, improve storage density, and reduce storage cost. For example, the HDD is replaced with 4.5-bit NAND, that is, the purpose of large capacity, high density and low cost is achieved. According to the implementation of the present disclosure, for the hard disk replacement demand, 4.5-bit NAND technology is proposed and studied. 4.5-bit NAND refers to a technique between QLC (1 memory cell stores 4 bits, 16 states) and PLC (1 memory cell stores 5 bits, 32 states, e.g., M=5), and has a total of 24 states, that is 1 erase state and 23 program states. To distinguish between these 24 states, there are a total of 23 read voltages. For example, 2 memory cells may be bundled, each of the 2 memory cells has 24 states respectively, and 24×24 is equal to 576 states, 512 of which are reserved, and that is 2 to the power of 9, that is, achieving 9 bits by using 2 memory cells, that is, equivalent to 1 memory cell storing 4.5 bits. By storing multiple bits of data in a single memory cell, the storage capacity is increased.

To implement 4.5-bit NAND, increasing the read window margin is an important task in order to meet the reliability requirements, which is the range of voltage or current fluctuations that can be tolerated by the memory cells of the NAND when reading data, which ensures that data can still be read correctly even in the presence of certain process deviations, operating condition variation, or interference. For 4.5-bit NAND, because the number of the program states increases, increasing the read window margin is important in order to increase reliability. At the same time, the 4.5-bit NAND does not place a very high requirement on tR (Read Latency, that is, the time required from the time when the NAND flash memory receives the read command to the time when the page buffer inside the flash memory actually senses (reads) the data), and therefore the implementation of the present disclosure can improve the read window margin by reading the individual bits in the same memory cell for multiple times. In addition, since the memory according to the implementations of the present disclosure is applied to a scenario for replacing HDD, while the HDD is used for cold data processing, a large storage capacity and a large density, but a relatively small number of readings are required. It should be noted that the solutions according to the implementations of the present disclosure may be applied to all NAND products, such as TLC, QLC, and the like.

In NAND, different program states are distinguished through different threshold voltages (Vth). In practice, threshold voltage (Vth) distributions of different program states may overlap due to factors such as process deviation, operating condition variation, interference, and the like. When the threshold voltage distributions of different program states overlap, voltage values that would otherwise represent different data states may become difficult to distinguish, resulting in read errors. These read errors cause an increase in FBC (Fail Bit Count). FBC represents the number of failed bits due to various reasons during read. To ensure the read reliability of the NAND, an ECC (error correction code) is adopted to correct errors that occur during the read process. However, the error correction capability of the ECC is limited. Therefore, in order to ensure the read reliability of the NAND, FBC is required to not exceed the error correction limit of the ECC.

Table 1 below is the read window margin (in mV) for performing one read on the memory cells in the 4.5-bit NAND (e.g., the read data obtained after reading for 1 time is directly used as the read result of the memory cell).

TABLE 1
Read

| Window | Vrd1 | | Vrd2 | | Vrd3 | |
|---|---|---|---|---|---|---|
| Margin | E0 = 70 | E1 = 90 | E2 = −20 | E3 = −30 | E4 = −20 | E5 = −10 |

| | | | |
|---|---|---|---|
| FBC | 7 | 52 | 42 |

Read

| Window | Vrd4 | | Vrd5 | | Vrd6 | |
|---|---|---|---|---|---|---|
| Margin | E6 = −30 | E7 = −20 | E8 = 0 | E9 = −10 | E10 = −10 | E11 = −30 |

| | | | |
|---|---|---|---|
| FBC | 46 | 33 | 39 |

Read

| Window | Vrd7 | | Vrd8 | | Vrd9 | |
|---|---|---|---|---|---|---|
| Margin | E12 = −20 | E13 = −10 | E14 = 0 | E15 = −30 | E16 = −10 | E17 = −20 |

| | | | |
|---|---|---|---|
| FBC | 36 | 37 | 35 |

Read

| Window | Vrd10 | | Vrd11 | | Vrd12 | |
|---|---|---|---|---|---|---|
| Margin | E18 = −20 | E19 = −20 | E20 = −10 | E21 = −30 | E22 = −30 | E23 = −20 |

| | | | |
|---|---|---|---|
| FBC | 36 | 40 | 42 |

Read

| Window | Vrd13 | | Vrd14 | | Vrd15 | |
|---|---|---|---|---|---|---|
| Margin | E24 = −30 | E25 = −30 | E26 = −40 | E27 = −30 | E28 = −30 | E29 = −40 |

| | | | |
|---|---|---|---|
| FBC | 47 | 57 | 57 |

Read

| Window | Vrd16 | | Vrd17 | | Vrd18 | |
|---|---|---|---|---|---|---|
| Margin | E30 = −40 | E31 = −40 | E32 = −40 | E33 = −40 | E34 = −40 | E35 = −50 |

| | | | |
|---|---|---|---|
| FBC | 71 | 73 | 75 |

Read

| Window | Vrd19 | | Vrd20 | | Vrd21 | |
|---|---|---|---|---|---|---|
| Margin | E36 = −40 | E37 = −50 | E38 = −50 | E39 = −50 | E40 = −50 | E41 = −40 |

| | | | |
|---|---|---|---|
| FBC | 69 | 73 | 83 |

Read

| Window | Vrd22 | | Vrd23 | |
|---|---|---|---|---|
| Margin | E42 = −50 | E43 = −20 | E44 = −30 | E45 = −30 |

| | | |
|---|---|---|
| FBC | 52 | 53 |

In Table 1 above, Vrd represents the read voltage applied to the selected word line (e.g., the target word line). A total of 23 Vrds are configured to distinguish among 24 states, which are gradually increased from Vrd1 to Vrd23, and their specific values may be set according to actual needs, which is not limited in the present disclosure. E0 represents the range moving from Vrd1 to the left within which the FBC does not exceed the ECC limit, e.g., still in the range within which error is correctable. E1 represents the range moving from Vrd1 to the right within which the FBC does not exceed the ECC limit, e.g., still in the range within which error is correctable. The sum of the absolute value of E0 and the absolute value of E1 represents the read window margin of Vrd1. Cases are similar for the others. Here, it is assumed that the ECC limit=14/2 kilobytes (KB) for each page, assuming that one page has 16 KB memory cells, which are divided into 8 groups each of which has 2 KB memory cells, 2 KB memory cells are read to compare each time the reading is performed, and 14 represents the ECC error correction limit of this page. However, these values are examples only, and may be changed to other values in the actual scenarios. It can be seen from Table 1 that E0=70 mV, Esum=−1170 mV, E0+Esum (which represents the sum of read window margins on all levels, e.g., 24 states)=−1100 mV.

By reducing the step voltage of the ISPP (Incremental Step Pulse Programming) during programming, the threshold voltage distribution can be made compact, so that the read window margin of the 4.5-bit NAND can be increased, but this is not a linear relationship, that is, when the step voltage of the ISPP is reduced to a certain extent (e.g., as small as 0.175V), the read window margin does not increase, or the increase is not obvious. In this case, the RTN (Random Telegraph Noise) noise during the read operation will be the major obstacle faced by the read window margin tolerance.

In low voltage environments, RTN noise may become a major obstacle that affects the margin during read operations. The RTN noise is related to states of traps in the semiconductor device, these traps can trap and release carriers, causing random fluctuations in the threshold voltage or conductivity of the device. In a memory device, such as a flash memory, such noise may cause a read error because it changes the apparent state of the memory cell. When the ISPP voltage decreases, the operation point of the device is closer to the energy level of these trap states, thereby increasing the effect of RTN noise. In this case, it is required to reduce the RTN noise to increase the read window margin of 4.5-bit NAND.

In the implementations of the present disclosure, considering that the RTN noise can cause a program state read error near Vrd, this effect is random, for example, assuming that ER, P1 to P23 respectively represent the erase state and the 23 memory states in the 4.5-bit NAND, and Vrd8 is configured to distinguish between P7 (the seventh memory state) and the P8 (the eighth memory state), the random noise can cause the read error of Vth threshold voltage near Vrd8, for example, reading the P8 as P7 incorrectly, that is, causing the FBC. The read result is determined by reading the same target memory cell for multiple times, so that the FBC is reduced, that is, the RTN noise is reduced, the range of the read voltage shifting to the left and the right is increased without affecting the space of the FBC, that is, the read window margin is increased essentially.

In an example implementation, the latch circuit is configured to store k read data of the m-th bit data in the target memory cell. The logic operation circuit is configured to: perform a logic operation on the k read data of the m-th bit data stored in the latch circuit to obtain a logic operation result, and store the logic operation result into the latch circuit; and obtain a read result of the m-th bit data according to the logic operation result in the latch circuit; and store a read result of the m-th bit data into the latch circuit.

In an example implementation, k=3; the latch circuit comprises first to fourth latch circuits, and first to third read data of the m-th bit data are respectively stored into the first to third latch circuits; and the logic operation circuit comprises first to third AND gates, and an OR gate.

The first AND gate is configured to: use the first read data in the first latch circuit and the second read data in the second latch circuit as the first input and the second input respectively to obtain a first AND result, and store the first AND result into the fourth latch circuit.

The second AND gate is configured to: use the first read data in the first latch circuit and the third read data in the third latch circuit as the first input and the second input respectively to obtain a second AND result, and store the second AND result into the first latch circuit.

The third AND gate is configured to: use the second read data in the second latch circuit and the third read data in the third latch circuit as the first input and the second input respectively to obtain a third AND result, and store the third AND result into the second latch circuit or the third latch circuit, and the logic operation result comprises the first AND result, the second AND result, and the third AND result.

The OR gate is configured to: use the first AND result in the fourth latch circuit, the second AND result in the first latch circuit, and the third AND result in the second latch circuit or the third latch circuit as the first input to the third input respectively to obtain a read result of the m-th bit data in the M bits of data stored in the target memory cell.

In the following description, taking k=3 as an example, that is, in a read operation for the same bit of the same target memory cell, the final read result will be determined by reading the data consecutively for three times. The rule of the truth table is shown in Table 2 below.

TABLE 2

| Read time | Data in C latch | | | | | | | |
|---|---|---|---|---|---|---|---|---|
| 1 | 0 | 1 | 0 | 0 | 1 | 1 | 1 | 0 |
| 2 | 0 | 1 | 0 | 1 | 0 | 1 | 0 | 1 |
| 3 | 0 | 1 | 1 | 0 | 0 | 0 | 1 | 1 |
| Final result | 0 | 1 | 0 | 0 | 0 | 1 | 1 | 1 |

The truth table in Table 2 is for each page bit (which may be any bit in the M bits) in the same memory cell (the target memory cell), that is, each page bit in one memory cell is read consecutively for 3 times, Read time represents the number of reading, Final result represents the final result, that is, the read result determined according to the read data for 3 times, and Data in C latch represents that the read data each time and the final read result are stored in the corresponding latch circuit. It can be seen from the table 2, the logic of the truth table is that when one bit of the same memory cell is read consecutively for 3 times, if there are 2 or more read data in the 3 read results being “0” (a first value), the read result of the bit of the memory cell is determined as “0” (the first value); and if there are 2 or more read data in the 3 read results being “1” (a second value), the read result of the bit of the memory cell is determined as “1” (the second value).

In the implementation of the present disclosure, the logic implementation of the truth table does not require an additional physical circuit, and nor requires the participation of the memory controller, and can be implemented by only requiring the memory controller to send, to the peripheral circuit, a read command to read the same memory cell consecutively for 3 times, and it can be implemented by writing it in the firmware of the read-only memory (ROM) of the memory controller and running the firmware.

In the implementation of the present disclosure, for 4.5-bit NAND, one memory cell has 5 bits. The implementation of the present disclosure may be implemented directly in a page buffer of a peripheral circuit of a memory. For 4.5-bit NAND, there are 6 latches in the page buffer, comprising 3 data latches D1 to D3 (e.g., the first to third data latch), one SA latch (sense latch), one C latch (cache latch, also abbreviated as CA latch), and one bit line latch. First, the first to the third read data of the current bit of the target memory cell are sequentially read from the target bit line to the SA latch, and then the first to the third read data are respectively put into the ABC three latches (which may be any three of D1 to D3 and the bit line latch). Then, the intersection of the first read data and the second read data in the AB two latches is computed (e.g., a logic AND operation is performed) to obtain a first AND result, the first AND result is put into the fourth latch (which may be any one of the D1 to the D3 and the bit line latch other than ABC), then the intersection of the first read data and the third read data in the AC two latches is computed (e.g., a logic AND operation is performed) to obtain a second AND result, and at this time, the second AND result may be put into the A latch to overwrite the first read data originally stored in the A latch, because the first read data in the A latch is no longer needed at this time. Then, the intersection of the second read data and the third read data in the BC two latches is computed (e.g., a logic AND operation is performed) to obtain a third AND result, and at this time, any one of B and C latches may be overwritten by the third AND result, and then a logic OR operation is performed on the first AND result, the second AND result, and the third AND result stored in the corresponding latches to obtain a read result, and the read result is stored in the C latch. That is, the method according to the implementations of the present disclosure can be implemented by using the existing latches in the page buffer, without the need for additional latches. That is, when the same bit in the same memory cell is read consecutively for 3 times, the read result can be determined directly by using the 6 latches in the NAND, without adding latches extra.

It should be noted that the method according to the implementations of the present disclosure may be applied to consecutive reads of more times, for example, may be extended to consecutive reads of odd number times, such as 5, 7, 9 times, etc. For example, if the same bit of the same memory cell is read consecutively for 5 times, in the 5 read data obtained after the same bit of the memory cell is read consecutively for 5 times, if there are 3 or more read data being 0, the final read result is 0; and if there are 3 or more read data being 1, the final read result is 1. That is, the higher the number of consecutive reads, the lower the FBC, and the more the read window margin increases, but there is corresponding increase in tR. If taking consecutive read of odd number times, such as 5, 7, 9 times, etc., in order to implement the foregoing similar truth table, it is required to add latches in the page buffer. The multiple reads can reduce the FBC, so that the space that the Vrd shifts to left and right increases, which is equivalent to increasing the read window margin, reducing the RTN noise in the read operation, and improving the tolerance of the ECC.

Table 3 below is the read window margin (in mV) for reading the memory cell in the 4.5-bit NAND for 3 times (e.g., reading the read data obtained for 3 times to determine the read result of the memory cell).

TABLE 3
Read

| Window | Vrd1 | | Vrd2 | | Vrd3 | |
|---|---|---|---|---|---|---|
| Margin | E0 = 60 | E1 = 100 | E2 = −20 | E3 = −30 | E4 = −20 | E5 = −10 |

| | | | |
|---|---|---|---|
| FBC | 7 | 42 | 38 |

Read

| Window | Vrd4 | | Vrd5 | | Vrd6 | |
|---|---|---|---|---|---|---|
| Margin | E6 = −20 | E7 = −10 | E8 = 0 | E9 = −10 | E10 = 0 | E11 = −30 |

| | | | |
|---|---|---|---|
| FBC | 39 | 26 | 33 |

Read

| Window | Vrd7 | | Vrd8 | | Vrd9 | |
|---|---|---|---|---|---|---|
| Margin | E12 = −10 | E13 = −10 | E14 = 0 | E15 = −20 | E16 = −10 | E17 = −10 |

| | | | |
|---|---|---|---|
| FBC | 33 | 29 | 34 |

Read

| Window | Vrd10 | | Vrd11 | | Vrd12 | |
|---|---|---|---|---|---|---|
| Margin | E18 = −20 | E19 = −10 | E20 = −10 | E21 = −30 | E22 = −20 | E23 = −20 |

| | | | |
|---|---|---|---|
| FBC | 31 | 36 | 40 |

Read

| Window | Vrd13 | | Vrd14 | | Vrd15 | |
|---|---|---|---|---|---|---|
| Margin | E24 = −30 | E25 = −30 | E26 = −30 | E27 = −30 | E28 = −30 | E29 = −40 |

| | | | |
|---|---|---|---|
| FBC | 44 | 54 | 56 |

Read

| Window | Vrd16 | | Vrd17 | | Vrd18 | |
|---|---|---|---|---|---|---|
| Margin | E30 = −50 | E31 = −40 | E32 = −30 | E33 = −40 | E34 = −40 | E35 = −50 |

| | | | |
|---|---|---|---|
| FBC | 71 | 70 | 71 |

Read

| Window | Vrd19 | | Vrd20 | | Vrd21 | |
|---|---|---|---|---|---|---|
| Margin | E36 = −40 | E37 = −50 | E38 = −50 | E39 = −40 | E40 = −50 | E41 = −40 |

| | | | |
|---|---|---|---|
| FBC | 64 | 72 | 77 |

Read

| Window | Vrd22 | | Vrd23 | |
|---|---|---|---|---|
| Margin | E42 = −50 | E43 = −20 | E44 = −30 | E45 = −30 |

| | | |
|---|---|---|
| FBC | 47 | 49 |

Taking the ECC limit=14/2 KB for each page as an implementation, it can be seen from Table 3 that E0=60 mV, Esum=−1060 mV, E0+Esum=−1000 mV. That is, applying a method of multiple reads may result in a read window margin gain of approximately 100 mV and a reduction of approximately 28 FBC per 2 KB for each page. It should be noted that in some cases in Table 3, the FBC is not improved, which is normal, because RTN is a random noise, and it is not required that the FBC at each Vrd is reduced, but an overall reduction is sufficient.

In an example implementation, the latch circuit further comprises a cache latch; an output terminal of the OR gate is coupled to an input terminal of the cache latch. The cache latch is configured to receive and store the read result of the m-th bit data from the output terminal of the OR gate.

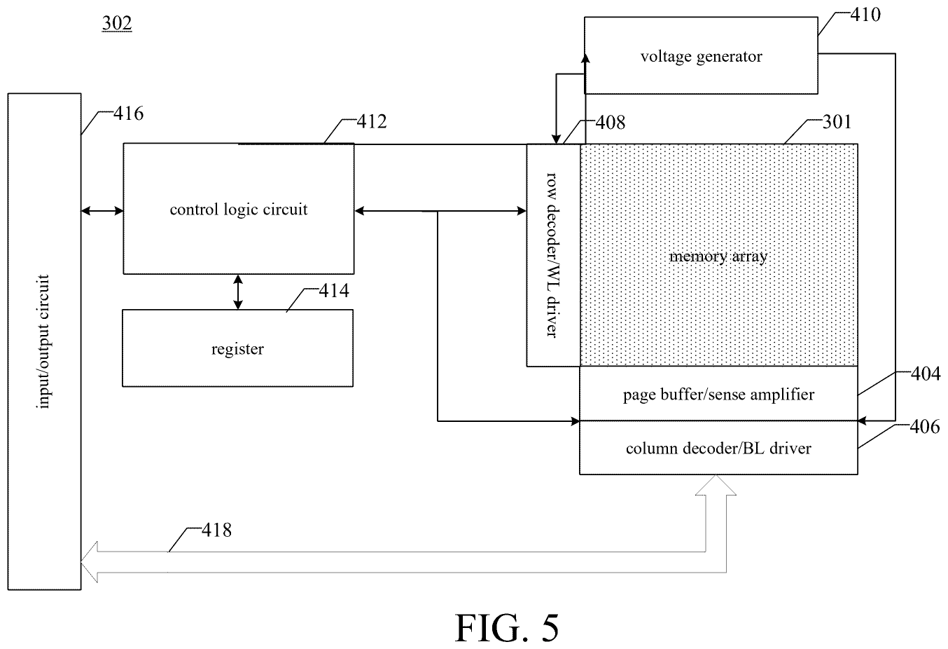

FIG. 5 is a schematic diagram of a peripheral circuit according to an implementation of the present disclosure. As shown in FIG. 5, the peripheral circuit 302 may comprise a page buffer/sense amplifier 404, a column decoder/BL driver 406, a row decoder/WL driver 408, a voltage generator 410, a control logic circuit 412, a register 414, an input/output (I/O) circuit 416, and a data bus 418. It should be understood that in some implementations, additional peripheral circuits not shown in FIG. 5 may also be comprised.

In some implementations, the page buffer/sense amplifier 404 may be configured to read data from and program (write) data to the memory array 301 according to control signals (comprising read commands) from the control logic circuit 412. For example, the page buffer/sense amplifier 404 may store a page of program data (write data) to be programmed into the memory array 301. For another implementation, the page buffer/sense amplifier 404 may also sense a low power signal from the bit line 316 representing a data bit stored in the memory cell 306, and amplify the small voltage swing to an identifiable logic level in a read operation. Column decoder/BL driver 406 may be configured to be controlled by the control logic circuit 412 and select one or more memory strings 308 by applying a bit line voltage generated from the voltage generator 410.

The row decoder/WL driver 408 may be configured to be controlled by the control logic circuit 412 and select/deselect the block 304 of the memory array 301 and select/deselect the word line 318 of the block 304. The row decoder/WL driver 408 may also be configured to drive the word line 318 using the word line voltage generated from the voltage generator 410. In some implementations, the row decoder/WL driver 408 may also select/deselect and drive a SSG line 315 and a DSG line 313. The voltage generator 410 may be configured to be controlled by the control logic circuit 412 and generate word line voltages (e.g., read voltages, program voltages, pass voltages, local voltages, verify voltages, etc.), bit line voltages, and source line voltages, etc. to be supplied to the memory array 301.

The control logic circuit 412 may be coupled to each part of the peripheral circuit 302 and configured to control an operation of each part. The registers 414 may be coupled to the control logic circuit 412 and may comprise status registers, command registers, and address registers for storing status information, command operation codes (OP codes), and command addresses for controlling operation of each peripheral circuit. The input/output circuit 416 may be coupled to the control logic circuit 412 and act as a control buffer to buffer control commands received from the host (not shown in FIG. 4) and relay them to the control logic circuit 412, and to buffer status information received from the control logic circuit 412 and relay it to the host. The input/output circuit 416 may also be coupled to the column decoder/bit line driver 406 via the data bus 418 and act as a data I/O interface and a data buffer to buffer data and relay it to the memory array 301 or relay or buffer data from the memory array 301.

In the read operation on the M-level cell type memory, multiple read data can be obtained by reading the same page bit of the same memory cell consecutively for multiple times, and the read result of the same page bit of the same memory cell is determined according to the multiple read data, so that the read margin is increased, the read reliability of the M-level cell type memory is improved, and the performance of the memory is improved.

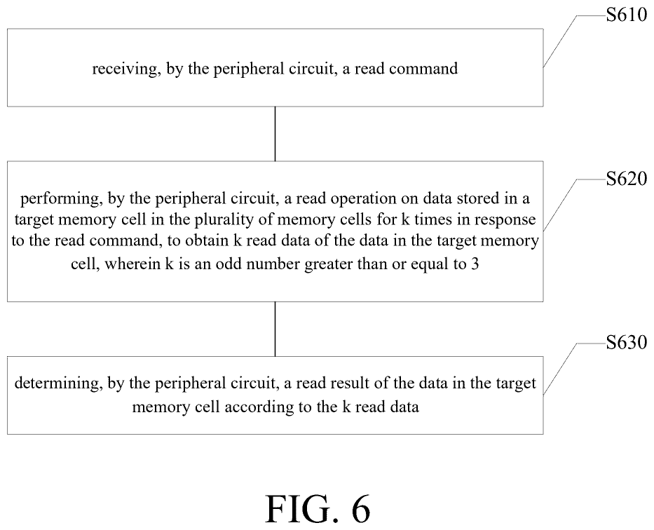

FIG. 6 is a flowchart illustrating an operation method of a memory according to an example implementation. The memory comprises a memory array and a peripheral circuit. The memory array comprises a plurality of memory cells. The method shown in FIG. 6 may be applied to the peripheral circuit shown in FIG. 5, for example. The method shown in FIG. 6 may be performed by sending an instruction (for example, a read command) to the peripheral circuit shown in FIG. 5 by the memory controller shown in FIG. 1, FIG. 2, or FIG. 3.

In an example implementation, the memory comprises a NAND memory.

As shown in FIG. 6, the method according to the implementation of the present disclosure comprises the following operations.

In S610, the peripheral circuit receives a read command.

In S620, the peripheral circuit performs a read operation for k times on data stored in a target memory cell in the plurality of memory cells in response to the read command, to obtain k read data of the data in the target memory cell, where k is an odd number greater than or equal to 3.

When a data read operation is performed on the non-volatile memory, in order to identify the data stored in the memory, a read voltage is applied to a word line (that is, a target word line) corresponding to a selected memory cell (that is, the target memory cell), a polarity of the applied read voltage is consistent with a polarity of a write voltage applied to the same word line when a data write (Program) operation is performed on the non-volatile memory, but a magnitude of the read voltage is smaller than a magnitude of the write voltage. The non-volatile memory comprises a plurality of memory cells, and a gate of each memory cell is connected to a corresponding one of the word lines. In the non-volatile memory, all the memory cells connected to the same word line are taken as a page, and each page has a corresponding page address. In an implementation, a data read operation may be performed on the memory cells connected to a word line, or a data read operation may be performed on a page address.

In S630, the peripheral circuit determines a reading result of the data in the target memory cell according to the k read data.

In an example implementation, a word line coupled to the target memory cell is a target word line; the data stored in the target memory cell comprises M bits, where M is a real number greater than 1; and the peripheral circuit comprises a control logic circuit.

In an example implementation, M=4.5, the target memory cell has any one of 23 memory states, and the 4.5 bit data stored in the target memory cell is distinguished to belong to any one of the 23 memory states through 22 different read voltages.

In the implementation of the present disclosure, a read operation is performed on the selected memory cell in any one of the erase state and the first memory state to the twenty-third memory state, and the adjacent pair of states are separated by respective threshold voltages.

In an example implementation, the peripheral circuit performing a read operation for k times on data stored in a target memory cell in the plurality of memory cells in response to the read command, to obtain k read data of the data in the target memory cell, comprises: applying, by the control logic circuit, a m-th read voltage to the target word line for k times in response to the read command, to perform the read operations for k times on an m-th bit data in M bits of data stored in the target memory cell, to obtain k read data of the m-th bit data stored in the target memory cell, where m is a real number greater than or equal to 1 and less than or equal to M.

In an example implementation, the m-th read voltage comprises at least two different read voltages.

In an example implementation, the method according to the implementation of the present disclosure further comprises: receiving, by the peripheral circuit, address information; and determining, by the peripheral circuit, the target memory cell from the plurality of memory cells according to the address information.

In S630, the peripheral circuit determines a read result of the data in the target memory cell according to the k read data.

In an example implementation, the peripheral circuit determining a read result of the data in the target memory cell according to the k read data comprises: determining, by the control logic circuit, a read result of the m-bit data in the M bits of data stored in the target memory cell according to the k read data of the m-th bit data stored in the target memory cell.

In an example implementation, the determining, by the control logic circuit, a read result of the m-bit data in the M bits of data stored in the target memory cell according to the k read data of the m-th bit data stored in the target memory cell comprises: if there are

$$\frac{k + 1}{2}$$

or more read data in the k read data of the m-th bit data stored in the target memory cell being the first value, determining the read result of the m-th bit data in the M bits of data stored in the target memory cell as the first value; and if there are

$$\frac{k + 1}{2}$$

or more read data in the k read data of the m-th bit data stored in the target memory cell being the second value, determining the read result of the m-th bit data in the M bits of data stored in the target memory cell as the second value.

In an example implementation, k=3; a bit line coupled to the target memory cell is a target bit line; and the peripheral circuit further comprises a plurality of page buffers, where one of the plurality of page buffers is coupled to one bit line, and a page buffer coupled to the target bit line comprises a latch circuit and a logic operation circuit.

The determining, by the control logic circuit, a read result of the m-bit data in the M bits of data stored in the target memory cell according to the k read data of the m-th bit data stored in the target memory cell comprises: controlling, by the control logic circuit, the latch circuit in the page buffer coupled to the target bit line to store k read data of the m-th bit data in the target memory cell; performing, by the logic operation circuit, a logic operation on the k read data of the m-th bit data stored in the latch circuit to obtain a logic operation result, and storing the logic operation result into the latch circuit; and obtaining the read result of the m-th bit data according to the logic operation result in the latch circuit.

In an example implementation, k=3; and the latch circuit comprises first to fourth latch circuits, and first to third read data of the m-th bit data are respectively stored into the first to third latch circuits.

In an example implementation, the performing, by the logic operation circuit, a logic operation on the k read data of the m-th bit data stored in the latch circuit to obtain a logic operation result, and storing the logic operation result into the latch circuit comprises: performing a logic AND operation on the first read data in the first latch circuit and the second read data in the second latch circuit to obtain a first AND result, and storing the first AND result into a fourth latch circuit; performing a logic AND operation on the first read data in the first latch circuit and the third read data in the third latch circuit to obtain a second AND result, and storing the second AND result into the first latch circuit; and performing a logic AND operation on the second read data in the second latch circuit and the third read data in the third latch circuit to obtain a third AND result, and storing the third AND result into the second latch circuit or the third latch circuit, where the logic operation result comprises the first AND result, the second AND result, and the third AND result.

In an example implementation, the obtaining the read result of the m-th bit data according to the logic operation result in the latch circuit comprises: performing a logic OR operation on the first AND result in the fourth latch circuit, the second AND result in the first latch circuit, and the third AND result in the second latch circuit or the third latch circuit to obtain the read result of the m-th bit data in the M bits of data stored in the target memory cell.

In an example implementation, the first to fourth latch circuits multiplex four of a sense latch, a bit line latch, a cache latch, and first to third data latches in a page buffer coupled to the target bit line. The method further comprises: storing the read result of the m-th bit data into the cache latch.

In a NAND memory, the memory cells coupled to one word line is a physical page/memory page, a physical page may be divided into a plurality of logical pages according to a number of bits of data stored in the memory cell, where the number of the divided logical pages is equal to the number of bits of data stored in the memory cell. For example, when the memory cell is a TLC flash memory, data stored in each memory cell has three bits, and correspondingly, one physical page may be divided into three logical pages, comprising lower logical page/lower page (LP) data, middle logical page/middle page (MP) data, and higher logical page/upper page (UP) data. For another implementation, when the memory cell is a QLC flash memory, data stored in each memory cell has 4 bits, and correspondingly, one physical page may be divided into 4 logical pages, comprising lower logical page/lower page (LP) data, middle logical page/middle page (MP) data, higher logical page/upper page (UP) data, and top page data.

The following illustrates a mapping scheme of a logical page (e.g., each bit in a target memory cell) and a state of a NAND flash memory according to some implementations of the present disclosure. In some implementations, the 2^{M} states of the M-bit memory cell may be represented in the form of Gray code. Gray code is an ordering of binary digit system such that two consecutive values differ only in one bit (binary digit).

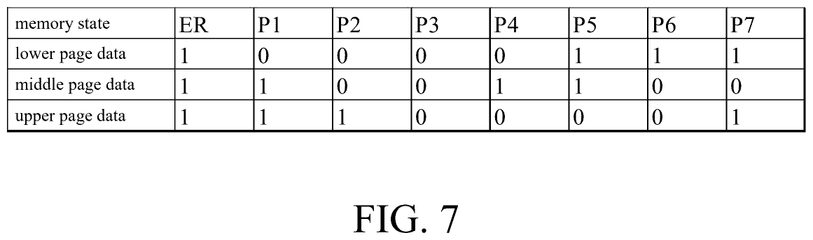

FIG. 7 is a schematic diagram illustrating a Gray code diagram of a TLC according to an example implementation. FIG. 7 shows an implementation binary code representation of eight states (erase state ER and memory states P1-P7) in TLC mode. For example, the erase state ER may correspond to a 3-bit binary code (111), while the memory states P1-P7 correspond to (011), (001), (000), (010), (110), (100), and (101), respectively. However, the present disclosure is not limited thereto, for example, in other implementations, the memory states P1-P7 correspond to (110), (100), (000), (010), (011), (001), and (101), respectively. Alternatively, the eight states of ER and P1-P7 of the TLC mode may be mapped to binary codes (111), (000), (001), (010), (100), (011), (101), and (110), respectively, using another mapping scheme. The 3 bits (read from left to right) of the binary code may be named as a most significant bit (MSB), a center significant bit (CSB), and a least significant bit (LSB). For example, state P5 may be mapped to binary code (011), where the MSB, CSB, and LSB are “0”, “1”, and “1”, respectively. In some implementations, the memory cells in the same memory page may be read or programmed simultaneously. Thus, each memory page of the TLC mode may be read by using read data from 3 logical pages (e.g., lower page data, middle page data, and upper page data) corresponding to the LSB, CSB, and MSB of the binary code, respectively. The methods disclosed herein may be applied to different sets of binary codes associated with states ER and P1-P7.

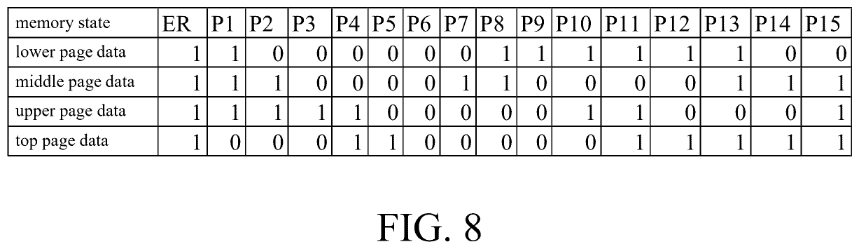

FIG. 8 is a schematic diagram illustrating a Gray code diagram of a QLC according to an example implementation. FIG. 8 illustrates a mapping scheme of binary codes to 16 QLC states according to some implementations of the present disclosure. In FIG. 8, a Gray code scheme may be adopted to represent each of the 16 states (erase state ER, and memory states P1-P15). For example, the erase state ER may correspond to a 4-bit binary code (1111), while the memory states P1-P15 correspond to (1110), (0110), (0010), (0011), (0001), (0000), (0100), (1100), (1000), (1010), (1011), (1001), (1101), (0101), and (0111), respectively. However, the present disclosure is not limited thereto.

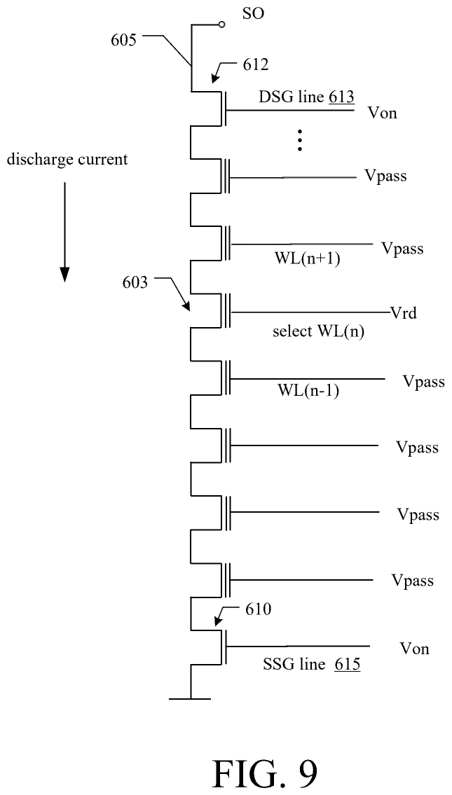

FIG. 9 is a schematic electrical diagram illustrating a memory string of a sense process according to an example implementation. As shown in FIG. 9, taking any one of the memory strings as an example, it is assumed that the gate of the DSG 612 is connected through the DSG line 613 to apply the Von voltage and/or the gate of the SSG 610 is connected through the SSG line 615 to apply the Von voltage, so that a certain memory string is selected, and memory cell 603 in the memory string is assumed to be the target memory cell, that is, the selected memory cell. A word line connected to the gate of the memory cell 603 is a target word line or is assumed to be a select WL(n). The word lines connected to the memory cells other than the memory cell 603 in the memory string are denoted as WL(1), . . . . WL(n−1), WL(n+1), etc. The drain of the DSG 612 is connected to the target bit line 605, and the target bit line 605 is connected to the SO node.

Each logical page corresponds to a different read voltage, and when data reading is performed on the memory cell 603, the read voltage Vrd corresponding to each logical page may be applied to the select word line WL(n) coupled to the memory cell 603 according to the order of the logical pages. After a read voltage corresponding to any logical page is applied to the select WL(n) each time, data of a corresponding bit stored in the memory cell 603 can be determined according to the conduction state of the target bit line 605 at different read voltages, and a read result is determined according to the read data of the corresponding bit. A turn-on voltage/pass voltage Vpass is applied to the gates of the unselected memory cells. The pass voltage Vpass applied to the word line may be higher than the maximum threshold voltage of the memory cells in the same word line, while the read voltage Vrd may be lower than the pass voltage Vpass.

The control logic circuit may be configured to initiate a read operation on the memory cell 603 through the page buffer and the SO node. The SO node may be a sense out node coupled to at least one of a bias circuit and a latch circuit. For example, the SO node may be any node in a connection line connected to each of the bias circuit and the latch circuit. To initiate a read operation on the memory cell 603, the control logic circuit may be configured to sense each of the M portions of the page data from the memory cell 603 one by one through the SO node. For example, for a QLC, the M portions of the page data may comprise lower page data, middle page data, upper page data, and top page data, respectively. The control logic circuit may be configured to read each of the lower page data, middle page data, upper page data, and top page data one by one from the memory cell 603 using the SO node and the cache latch.

After programming, 8 TLC states, e.g., ER and P1-P7, can be verified by using one or more read voltages Vrd1-Vrd7. By applying one or more of the read voltages Vrd1-Vrd7 to the control gate of the target memory cell, the range of the threshold voltage Vth of the target memory cell can be determined. For example, to verify whether the target memory cell is in the state ER, the read voltage Vrd1 may be used. If the target memory cell is in the state ER, the threshold voltage Vth of the target memory cell is lower than the read voltage Vrd1. The target memory cell may be turned on and a conductive path can be formed in the channel. If the target memory cell is in any of the states P1-P7, the threshold voltage Vth of the target memory cell is higher than the read voltage Vrd1. The target memory cell is thereby turned off. By measuring or sensing the current through the target memory cell at the corresponding bit line, the threshold voltage Vth or state of the target memory cell can be verified.

As described above, to determine the two states ER and P1 stored in SLC mode, only the read voltage Vrd1 is needed. To determine the four states ER and P1-P3 in MLC mode, read voltages Vrd1, Vrd2, and Vrd3 may be used. To determine eight states ER and P1-P7 of the TLC mode, read voltages Vrd1-Vrd7 may be used. For example, in TLC mode, the threshold voltage of state ER is lower than Vrd1, and the threshold voltage of state P7 is higher than Vrd7, wherein the threshold voltage of state P1 is between Vrd1 and Vrd2. The states P2-P6 may be similarly determined. Likewise, in the QLC mode, 15 read voltages can be adopted to verify 16 states (ER and P1-P15). To verify the 2^{M} states in MLC mode, 2^{M}−1 read voltages may be adopted. In some implementations, SLC reads may be performed to separate two groups of logic states using a single read voltage. For example, by comparing the threshold voltage of the memory cell to the read voltage Vrd4, the states ER and P1-P3 may be separated from the states P4-P7.

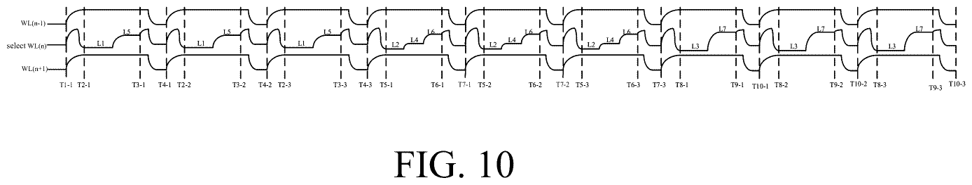

FIG. 10 is a schematic diagram illustrating a WL waveform of a TLC forward read according to an example implementation. FIG. 10 shows a schematic diagram of a read voltage applied on a control gate of a target memory cell. For different gray codes, 3 bits of data stored in the memory cell in each state are different. For the gray code shown in FIG. 7, the 3 bits of data stored in the memory cell in the ER state, the P1 state, the P2 state, the P3 state, the P4 state, the P5 state, the P6 state, and the P7 state are 111, 011, 001, 000, 010, 110, 100, 101, respectively. In the 3 bits of data stored in the memory cell in each state, the first bit data is the LP data (that is, the lower page data), the second bit data is the MP data (that is, the middle page data), and the third bit data is UP data (that is, the upper page data). The read voltages are represented by L1, L2, L3, L4, L5, L6, and L7 in FIG. 10. L1 is greater than the maximum threshold voltage of the memory cell in the ER state and less than the minimum threshold voltage of the memory cell in the P1 state, and correspondingly, the magnitude relationships between the L2 to L7 and the threshold voltages of the memory cell in the P1 state to the P7 state are similar.

When data reading is performed on any physical page, a read voltage corresponding to each logical page may be applied to a word line corresponding to the physical page according to an order of the logical pages. The order of the logical pages may be: reading the LP first, then reading the MP, and finally reading the UP. The order of the logical pages may also be: reading the LP first, then reading the UP, and finally reading the MP. This is not limited in the implementations of the present disclosure.

The read voltage corresponding to each logical page may be that: the read voltages corresponding to the LP are L1 and L5, the read voltages corresponding to the MP are L2, L4 and L6, and the read voltages corresponding to the UP are L3 and L7. When the LP is read, a L1 read voltage is applied to the word line corresponding to the physical page, the memory cell in the ER state in the physical page is turned on, and the LP data of the memory cell in the ER state may be read as 1. Then the L5 read voltage is applied to the word line corresponding to the physical page, the memory cells in the P1 state to the P4 state in the physical page are turned on, the LP data of the memory cells in the P1 state to the P4 state can be read as 0, and the LP data of the memory cell in the P5 state to the P7 state can be read as 1. In this way, the LP data of the memory cells in the P1 state to the P7 state may be obtained by applying the L1 read voltage and the L5 read voltage to the word line corresponding to the physical page. Correspondingly, the MP data of the memory cells in the P1 state to the P7 state may be obtained by applying the L2 read voltage, the L4 read voltage and the L6 read voltage to the word line corresponding to the physical page. The UP data of the memory cells in the P1 state to the P7 state may also be obtained by applying the L3 read voltage and the L7 read voltage to the word line corresponding to the physical page. For different gray codes, the read voltages corresponding to the LP, the UP and the MP are different. For example, it is assumed that the 3 bits of data stored in the memory cells in the ER state to the P7 state are 111, 011, 001, 101, 100, 000, 010, 110, respectively. The read voltage corresponding to the LP is L4, the read voltages corresponding to the MP are L2 and L6, and the read voltages corresponding to the UP are L1, L3, L5, and L7.

After any read voltage corresponding to any logical page is applied to the word line each time, the data of the corresponding bit stored in the target memory cell may be determined according to the conduction state of the target memory cell at different read voltages. In this way, after each read voltage corresponding to each logical page is applied to the word line, a read result may be determined according to the determined data of each bit stored in the target memory cell. A prepulse voltage is required to be applied to the word line corresponding to the physical page before the sense reading to clean the channel and solve the hot carrier injection (HCI) problem. Then, after the sense is completed, a recovery pulse voltage is applied to the word line corresponding to the physical page to clean the channel again. For example, an implementation in which the LP is read first, then the MP is read, and the UP is finally read in FIG. 10, is taken as an example for description. The control logic circuit receives a read command to read the LP (e.g., 20h), initializes the sense latch and the cache latch in the page buffer, e.g., the data stored in the sense latch and the cache latch is a sequence of all 1. Next, there are 4 phases: a prepulse phase, a read phase, and a recovery phase.

In the prepulse phase (T1-1 to T2-1), the control logic circuit applies a prepulse voltage to the selected word line (e.g., the target word line). In the read phase, the control logic circuit sequentially applies the L1 read voltage and the L5 read voltage to the selected word line (T2-1 to T3-1). In an implementation, the L1 read voltage is applied to the selected word line, in the plurality of memory cells coupled to the word line, the memory cell in the ER state is turned on, and the data stored in sense latch coupled to the bit line corresponding to the memory cell in the ER state becomes 0. The memory cells in the P1 state to the P7 state are not turned on, and the data stored in the sense latches corresponding to the memory cells in the P1 state to the P7 state is a sequence of all 1. The data in the sense latches corresponding to the memory cells in the ER state to the P7 state is inverted to obtain the data in the cache latches corresponding to the memory cells in the ER state to the P7 state. At this time, the first read data of the LP data of the memory cell in the ER state has been obtained and stored in the cache latch corresponding to the memory cell in the ER state. The L5 read voltage is applied to the selected word line, in the plurality of memory cells coupled to the word line, the memory cells in the P1 state to the P4 state are turned on, and the data stored in the sense latches coupled to the bit line corresponding to the memory cells in the P1 state to the P4 state becomes 0. The memory cells in the P5 state to the P7 state are not turned on, and the data stored in the sense latches corresponding to the memory cells in the P5 state to the P7 state is a sequence of all 1. The data in the sense latch corresponding to the memory cells in the P1 state to the P7 state is transmitted to the data in the cache latches corresponding to the memory cells in the P1 state to the P7 state. At this time, the first read data of the LP data of the memory cells in the P1 state to the P7 state has been obtained and stored in the cache latches corresponding to the memory cells in the P1 state to the P7 state.

In the recovery phase (T3-1 to T4-1), the control logic circuit applies a recovery pulse voltage to the selected word line. The control logic circuit outputs the data in the cache latches corresponding to the memory cells in the ER state to the P7 state, that is, the first read data of the LP data of the memory cells in the ER state to the P7 state is stored in the A latch above.

In the prepulse phase (T4-1 to T2-2), the control logic circuit applies a prepulse voltage to the selected word line. In the read phase (T2-2 to T3-2), the control logic circuit sequentially applies the L1 read voltage and the L5 read voltage to the selected word line. In an implementation, the L1 read voltage is applied to the selected word line to obtain the second read data of the LP data of the memory cell in the ER state, and store it in the cache latch corresponding to the memory cell in the ER state. The L5 read voltage is applied to the selected word line to obtain the second read data of the LP data of the memory cells in the P1 state to the P7 state, and store it in the cache latches corresponding to the memory cells in the P1 state to the P7 state. In the recovery phase (T3-2 to T4-2), the control logic circuit applies a recovery pulse voltage to the selected word line. The control logic circuit outputs the data in the cache latches corresponding to the memory cells in the ER state to the P7 state, that is, stores the second read data of the LP data of the memory cells in the ER state to the P7 state in the B latch above.

In the prepulse phase (T4-2 to T2-3), the control logic circuit applies a prepulse voltage to the selected word line. In the read phase (T2-3 to T3-3), the control logic circuit sequentially applies a L1 read voltage and a L5 read voltage to the selected word line. In an implementation, the L1 read voltage is applied to the selected word line to obtain the third read data of the LP data of the memory cell in the ER state, and store it in the cache latch corresponding to the memory cell in the ER state. The L5 read voltage is applied to the selected word line to obtain the third read data of the LP data of the memory cells in the P1 state to the P7 state, and store it in the cache latches corresponding to the memory cells in the P1 state to the P7 state. In the recovery phase (T3-3 to T4-3), the control logic circuit applies a recovery pulse voltage to the selected word line. The control logic circuit outputs the data in the cache latches corresponding to the memory cells in the ER state to the P7 state, that is, store the third read data of the LP data of the memory cells in the ER state to the P7 state in the above cache latches. Thereafter, a logic operation is performed on the first read data to the third read data of the LP data stored in the A, B latches and the cache latches, to determine a read result of the LP data.

The control logic circuit receives a read command to read the MP (e.g., 20h), and initializes the sense latch and the cache latch in the page buffer. In the prepulse phase (T4-3 to T5-1), the control logic circuit applies a prepulse voltage to the selected word line. In the read phase (T5-1 to T6-1), the control logic circuit sequentially applies the L2 read voltage, the L4 read voltage, and the L6 read voltage to the selected word line. In an implementation, the L2 read voltage is applied to the selected word line, and in the plurality of memory cells coupled to the word line, the memory cells in the ER state and P1 state are turned on, and the data stored in the sense latches coupled to the bit lines corresponding to the memory cells in the ER state and the P1 state becomes 0. The memory cells in the P2 state to the P7 state are not turned on, and the data stored in the sense latches corresponding to the memory cells in the P2 state to the P7 state is a sequence of all 1. The data in the sense latches corresponding to the memory cells in the ER state to the P7 state is inverted to obtain the data in the cache latches corresponding to the memory cells in the ER state to the P7 state. At this time, the first read data of the MP data of the memory cells in the ER state and the P1 state has been obtained and stored in the cache latches corresponding to the memory cells in the ER state and the P1 state. The L4 read voltage is applied to the selected word line, and in the plurality of memory cells coupled to the word line, the memory cells in the P2 state and P3 state are turned on, and the data stored in the sense latches coupled to the bit lines corresponding to the memory cells in the P2 state and the P3 state becomes 0. The memory cells in the P4 state to the P7 state are not turned on, and the data stored in the sense latches corresponding to the memory cells in the P4 state to the P7 state is a sequence of all 1. The data in the sense latches corresponding to the memory cells in the P2 state to the P7 state is transmitted to the data in the cache latches corresponding to the memory cells in the P2 state to the P7 state. At this time, the first read data of the MP data of the memory cells in the P2 state and the P3 state have been obtained and stored in the cache latches corresponding to the memory cells in the P2 state and the P3 state. The L6 read voltage is applied to the selected word line, and in the plurality of memory cells coupled to the word line, the memory cells in the P4 state and P5 state are turned on, and the data stored in the sense latches coupled to the bit lines corresponding to the memory cells in the P4 state and the P5 state becomes 0. The memory cells in the P6 state and the P7 state are not turned on, and the data stored in the sense latches corresponding to the memory cells in the P4 state to the P7 state is a sequence of all 1. The data in the sense latches corresponding to the memory cells in the P4 state to the P7 state is inverted to obtain the data in the cache latches corresponding to the memory cells in the P4 state to the P7 state. At this time, the first read data of the MP data of the memory cells in the P4 state to the P7 state has been obtained and stored in the cache latches corresponding to the memory cells in the P4 state to the P7 state. In the recovery phase (T6-1 to T7-1), the control logic circuit applies a recovery pulse voltage to the selected word line. The control logic circuit outputs the data in the cache latches corresponding to the memory cells in the ER state to the P7 state, that is, the first read data of the MP data of the memory cells in the ER state to the P7 state, into the A latch.

In the prepulse phase (T7-1 to T5-2), the control logic circuit applies a prepulse voltage to the selected word line. In the read phase (T5-2 to T6-2), the control logic circuit sequentially applies the L2 read voltage, the L4 read voltage, and the L6 read voltage to the selected word line. In an implementation, the L2 read voltage is applied to the selected word line to obtain the second read data of the MP data of the memory cells in the ER state and the P1 state, and store it in the cache latches corresponding to the memory cells in the ER state and the P1 state. The L4 read voltage is applied to the selected word line to obtain the second read data of the MP data of the memory cells in the P2 state and the P3 state, and store it in the cache latches corresponding to the memory cells in the P2 state and the P3 state. The L6 read voltage is applied to the selected word line to obtain the second read data of the MP data of the memory cells in the P4 state to the P7 state, and store it in the cache latches corresponding to the memory cell in the P4 state to the P7 state. In the recovery phase (T6-2 to T7-2), the control logic circuit applies a recovery pulse voltage to the selected word line. The control logic circuit outputs the data in the cache latches corresponding to the memory cells in the ER state to the P7 state, that is, the second read data of the MP data of the memory cells in the ER state to the P7 state, into the B latch.

In the prepulse phase (T7-2 to T5-3), the control logic circuit applies a prepulse voltage to the selected word line. In the read phase (T5-3 to T6-3), the control logic circuit sequentially applies the L2 read voltage, the L4 read voltage, and the L6 read voltage to the selected word line. In an implementation, the L2 read voltage is applied to the selected word line to obtain the third read data of the MP data of the memory cells in the ER state and the P1 state, and store it in the cache latches corresponding to the memory cells in the ER state and the P1 state. The L4 read voltage is applied to the selected word line to obtain the third read data of the MP data of the memory cells in the P2 state and the P3 state, and store it in the cache latches corresponding to the memory cells in the P2 state and the P3 state. The L6 read voltage is applied to the selected word line to obtain the third read data of the MP data of the memory cells in the P4 state to the P7 state, and store it in the cache latches corresponding to the memory cell in the P4 state to the P7 state. In the recovery phase (T6-3 to T7-3), the control logic circuit applies a recovery pulse voltage to the selected word line. The control logic circuit outputs the data in the cache latches corresponding to the memory cells in the ER state to the P7 state, that is, the third read data of the MP data of the memory cells in the ER state to the P7 state, into the C latch. A logic operation is performed on the first read data to the third read data of the MP data stored in A, B, and C latches to obtain a read result of the MP data.

The control logic circuit receives a read command to read the UP (e.g., 20h), and initializes the sense latch and the cache latch in the page buffer. In the prepulse phase (T7-3 to T8-1), the control logic circuit applies a prepulse voltage to the selected word line. In the read phase (T8-1 to T9-1), the control logic circuit sequentially applies the L3 read voltage and the L7 read voltage to the selected word line. In an implementation, the L3 read voltage is applied to the selected word line, and in the plurality of memory cells coupled to the word line, the memory cells in the ER state to P2 state are turned on, and the data stored in the sense latches coupled to the bit lines corresponding to the memory cells in the ER state to the P2 state becomes 0. The memory cells in the P3 state to the P7 state are not turned on, and the data stored in the sense latches corresponding to the memory cells in the P3 state to the P7 state is a sequence of all 1. The data in the sense latches corresponding to the memory cells in the ER state to the P7 state is inverted to obtain the data in the cache latches corresponding to the memory cells in the ER state to the P7 state. At this time, the first read data of the UP data of the memory cells in the ER state to the P2 state have been obtained and stored in the cache latches corresponding to the memory cells in the ER state to the P2 state. The L7 read voltage is applied to the selected word line, and in the plurality of memory cells coupled to the word line, the memory cells in the P3 state to P6 state are not turned on, and the data stored in the sense latches coupled to the bit lines corresponding to the memory cells in the P3 state to the P6 state becomes 0. The memory cell in the P7 state is not turned on, and the data stored in the sense latch corresponding to the memory cell in the P7 state is a sequence of all 1. The data in the sense latches corresponding to the memory cells in the P3 state to the P7 state is transmitted to the data in the cache latches corresponding to the memory cells in the P3 state to the P7 state. At this time, the first read data of the UP data of the memory cells in the P3 state to the P7 state has been obtained and stored in the cache latches corresponding to the memory cells in the P3 state to the P7 state. In the recovery phase (T9-1 to T10-1), the control logic circuit applies a recovery pulse voltage to the selected word line. The control logic circuit outputs the data in the cache latches corresponding to the memory cells in the ER state to the P7 state, that is, stores the first read data of the UP data of the memory cells in the ER state to the P7 state into the A latch.

In the prepulse phase (T10-1 to T8-2), the control logic circuit applies a prepulse voltage to the selected word line. In the read phase (T8-2 to T9-2), the control logic circuit sequentially applies the L3 read voltage and the L7 read voltage to the selected word line. In an implementation, the L3 read voltage is applied to the selected word line to obtain the second read data of the UP data of the memory cells in the ER state to the P2 state, and store it in the cache latches corresponding to the memory cells in the ER state to the P2 state. The L7 read voltage is applied to the selected word line to obtain the second read data of the UP data of the memory cells in the P3 state to the P7 state, and store it in the cache latches corresponding to the memory cell in the P3 state to the P7 state. In the recovery phase (T9-2 to T10-2), the control logic circuit applies a recovery pulse voltage to the selected word line. The control logic circuit outputs the data in the cache latches corresponding to the memory cells in the ER state to the P7 state, that is, stores the second read data of the UP data of the memory cells in the ER state to the P7 state into the B latch.

In the prepulse phase (T10-2 to T8-3), the control logic circuit applies a prepulse voltage to the selected word line. In the read phase (T8-3 to T9-3), the control logic circuit sequentially applies the L3 read voltage and the L7 read voltage to the selected word line. In an implementation, the L3 read voltage is applied to the selected word line to obtain the third read data of the UP data of the memory cells in the ER state to the P2 state, and store it in the cache latches corresponding to the memory cells in the ER state to the P2 state. The L7 read voltage is applied to the selected word line to obtain the third read data of the UP data of the memory cells in the P3 state to the P7 state, and store it in the cache latches corresponding to the memory cell in the P3 state to the P7 state. In the recovery phase (T9-3 to T10-3), the control logic circuit applies a recovery pulse voltage to the selected word line. The control logic circuit outputs the data in the cache latches corresponding to the memory cells in the ER state to the P7 state, that is, stores the third read data of the UP data of the memory cells in the ER state to the P7 state into the C latch. A logic operation is performed on the first read data to the third read data of the UP data stored in A, B, and C latches to obtain a read result of the UP data.

In the process of performing the read operation on the memory cell, since the memory states of the memory cell are different (e.g., “1” or “0” is stored in the memory cell), the generated channel current are different, and based on this, the memory state of the memory cell can be obtained by sensing the channel current, thereby obtaining the data stored in the memory cell. Considering that the channel current of the three-dimensional NAND memory is relatively small, it is difficult to directly measure the small current. In practical applications, the channel current is indirectly measured in a small-area page buffer by detecting the discharge of the sense node SO in the page buffer, thereby obtaining the memory state of the memory cell.

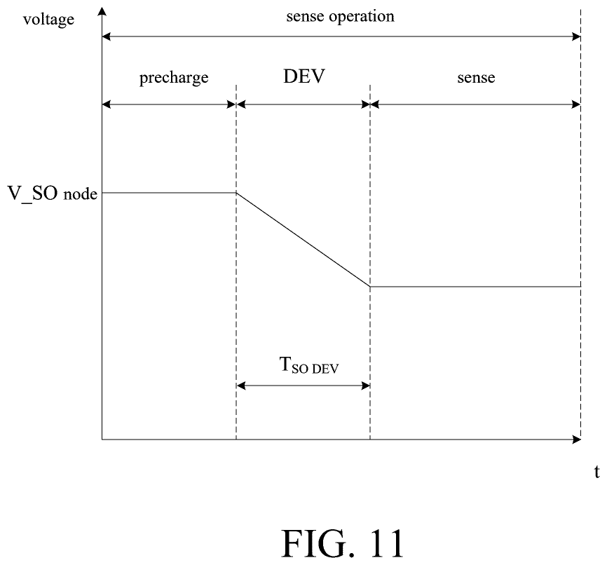

FIG. 11 is a schematic diagram illustrating a change of potential of a sense operation SO node according to an example implementation. In FIG. 11, the V_SO node represents the voltage value of the SO node, and the horizontal coordinate is time t. There may be a parasitic capacitor in the connecting lines of the SO node. When the SO node is controlled by the control logic circuit to perform precharge (or discharge), the parasitic capacitor in the connecting line is precharged (or discharged). Then, if the sense level (e.g., sense voltage level) is applied to the target memory cell coupled to the page buffer, the SO node is accordingly discharged (e.g., the higher the sense level, the faster the SO node discharges), e.g., is discharged in the time period TSO DEY shown in FIG. 11. Then, in the sense phase, a corresponding portion of the page data to be sensed from the target memory cell may be determined based on the potential value of the SO node.

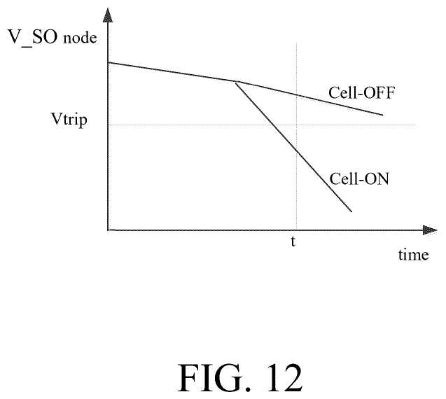

FIG. 12 is a schematic diagram illustrating a change of potential of an SO node corresponding to a memory cell that is turned on and turned off in a sense operation according to an example implementation. As shown in FIG. 12, when the read operation is performed, the sense node SO is firstly charged to a fixed voltage, the sense node SO is connected to the memory cell through the bit line, and if the read voltage applied when the read operation is performed can cause the memory cell to be turned on, after a period of time, the sense node SO is discharged due to the turn-on of the memory cell; if the read voltage applied when the read operation is performed cannot cause the memory cell to be turned on or only cause the memory cell to be weakly turned on, after a period of time, the sense node SO is almost not discharged. Based on this, the channel current can be indirectly measured by sensing the voltage change of the node SO, thereby obtaining the memory state of the memory cell.

As shown in FIG. 12, by sensing the change of the potential value of the V_SO node, it can be sensed whether the target memory cell is in the Cell-ON state or the Cell-OFF state. For example, a voltage value of the V_SO node may be compared with a predetermined threshold Vtrip at a predetermined time t, and the target memory cell is in Cell-Off state if the V_SO node is greater than Vtrip; and the target memory cell is in a Cell-On state if the V_SO node is less than Vtrip.

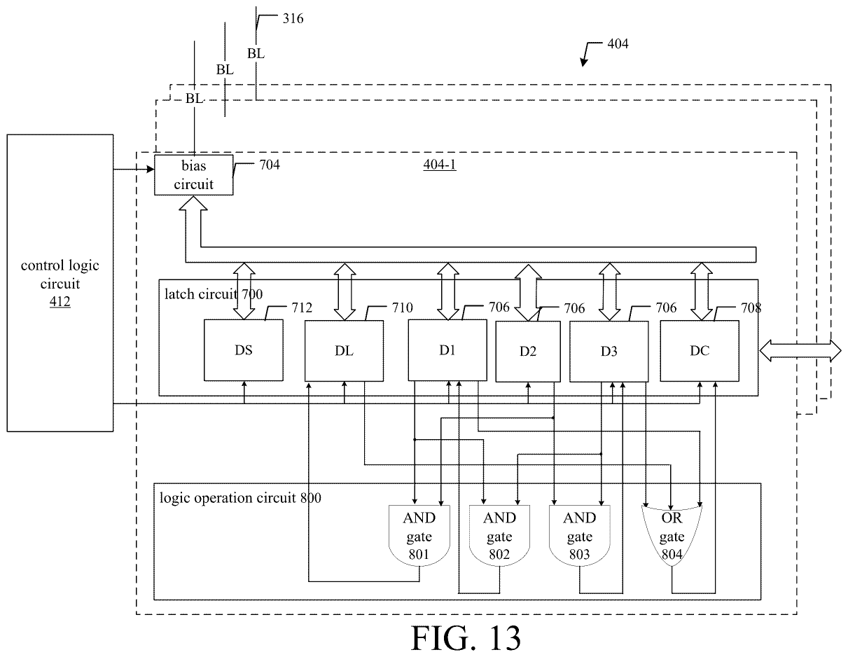

FIG. 13 is a circuit block diagram illustrating a page buffer 404 according to an example implementation. The page buffer 404 comprises a page buffer 404-1, a page buffer coupled to the target bit line. The control logic circuit 412 is configured to control the performance of the operation method according to the implementations of the present disclosure. In FIG. 13, the output of bias circuit 704 of the page buffer 404-1 is coupled to the SO node or a target bit line in the bit line BL 316. The page buffer 404-1 comprises a latch circuit 700. For example, the latch circuit 700 comprises first to third data latches D1, D2, and D3 (all labeled with 706), a cache latch DC 708, a sense latch DS 712, and a bit line latch DL 710 that may be coupled to the SO node, respectively.

With continued reference to FIG. 13, the page buffer 404-1 further adds a logic operation circuit 800. The logic operation circuit 800 comprises an AND gate 801 (a first AND gate), an AND gate 802 (a second AND gate), an AND gate 803 (a third AND gates), and an OR gate 804.

It is assumed that the first to third data latches D1, D2 and D3 act as the A, B and C latches respectively, e.g., the first to third latch circuits, and the bit line latch DL acts as the fourth latch circuit. The first input terminal and the second input terminal of the AND gate 801 are respectively connected to the output terminals of the first data latch D1 and the second data latch D2, to read the first read data of the m-th bit of the target memory cell stored in the first data latch D1 and the second read data of the m-th bit of the target memory cell stored in the second data latch D2, to obtain the first AND result. The output terminal of the AND gate 801 is connected to the first input terminal of the bit line latch DL to store the first AND result into the bit line latch DL.

The first input terminal and the second input terminal of the AND gate 802 are respectively connected to the output terminals of the first data latch D1 and the third data latch D3, to read the first read data of the m-th bit of the target memory cell stored in the first data latch D1 and the third read data of the m-th bit of the target memory cell stored in the third data latch D3, to obtain the second AND result. The output terminal of the AND gate 801 is connected to the first input terminal of the first data latch D1 to store the second AND result into the first data latch D1.

The first input terminal and the second input terminal of the AND gate 803 are respectively connected to the output terminals of the second data latch D2 and the third data latch D3, to read the second read data of the m-th bit of the target memory cell stored in the second data latch D2 and the third read data of the m-th bit of the target memory cell stored in the third data latch D3, to obtain the third AND result. The output terminal of the AND gate 803 is connected to the first input terminal of the third data latch D3 to store the third AND result into the third data latch D3.

The first input terminal, the second input terminal and the third input terminal of the OR gate 804 are respectively connected to the output terminal of the bit line latch DL, the output terminal of the first data latch D1, and the output terminal of the third data latch D3, to obtain a first AND result, a second AND result, and a third AND result, and perform a logic OR operation to obtain a read result of the m-th bit data in the M bits of data stored in the target memory cell.

According to the page buffer in the implementations of the present disclosure, by adding a small number of logic operation circuits therein and multiplexing the latches in the page buffer, a read operation is performed consecutively for k times on each bit of data in the M bits of data in the target memory cell, and k read data of each bit of data is obtained and stored, and the read result of each bit of data is obtained according to the k read data operations on each bit of data, on one hand, the hardware structure is simple, the influence on the area of the page buffer is not large, and on the other hand, the accuracy of the read result of the target memory cell can be improved.

In other implementations, the page buffer may also comprise an input circuit, a data output (DO) buffer, and a precharge circuit. In some implementations, the precharge circuit may operate in response to a precharge signal (e.g., Prech_all) to precharge the SO node. The input circuit may be configured to receive program data intended to be programmed into the memory device. For example, during a program operation, program data from an interface may be input to the cache latch DC 708 via an input circuit. For the read operations described herein, the read results stored in the cache latch DC 708 may be output to the interface through the data output buffer. The page buffer 404 may be configured to read data from and program (write) data to the memory array according to control signals from the control logic circuit 412. Each page buffer may be coupled to one bit line of the memory array. Each memory string is coupled to a bit line. Thus, memory cells on a memory string may be coupled to at least one page buffer. The page buffer may temporarily store data for memory cells in the memory array and then output the stored data.

In some implementations, the page buffer may comprise more data latches or control latches. In some implementations, the page buffer may comprise storage units other than latches.

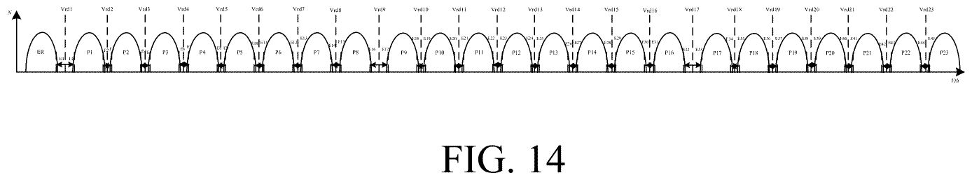

FIG. 14 is a schematic diagram illustrating a threshold voltage distribution of 4.5 LC according to an example implementation. Taking a 4.5 LC in which the memory cell contains 24 states as an example, the horizontal coordinate represents the threshold voltage distributions of 24 different states, wherein ER is the threshold voltage distribution of the erase state, and P1-P23 is the threshold voltage distributions of different program states (or memory states), the vertical ordinate represents the number of memory cells in each state, it can be seen that the number of memory cells in each state presents Gaussian distribution. The read voltage Vrd is between any two adjacent memory states, and the read voltages are Vrd1, Vrd2, Vrd3 to Vrd23 in ascending order. Vrd1 represents the default read voltage of the erase state, and the turn-on voltage Vpass is higher than the maximum value of the read voltage. The read voltage Vrd1 may be a read voltage by which the erase state ER and the program state P1 are separated from each other. The read voltage Vrd2 may be a read voltage by which the program state P1 and the program state P2 are separated from each other. The read voltage Vrd3 may be a read voltage by which the program state P2 and the program state P3 are separated from each other. Other read voltages are similar, until the read voltage Vrd23 can be a read voltage by which the program state P22 and the program state P23 are separated from each other.

FIG. 14 is a threshold voltage distribution in an ideal state. In practice, there may be overlap between adjacent threshold voltage distributions, resulting in FBC. The voltage thresholds comprise, for example, a total of 24 petals, ER and P0-P23, and a total of 46 edge distances, E0-E45. The FBC is generated under a certain read voltage because different voltage thresholds overlap with each other with the reliability stress; when the read voltage is at a valley bottom position of the overlap between the two voltage thresholds, an FBC minimum value is generated, which is referred to as an optimal read state FBC. The distance and the degree of overlap between different voltage thresholds can be characterized by the characterization value read window margin: the larger the read window margin is, the smaller the degree of overlap between different voltage thresholds is, the smaller the generated FBC is; and as the stress increases due to multiple reads and writes, the voltage threshold is broaden, the characterization value read window margin is reduced, and the generated FBC is correspondingly increased.

The present disclosure aims to provide an operation method of a memory, a memory, and a memory system.

According to an aspect of the present disclosure, an operation method of a memory is provided, wherein the memory comprises a memory array and a peripheral circuit. The memory array comprises a plurality of memory cells. The method comprises: receiving, by the peripheral circuit, a read command; performing, by the peripheral circuit, a read operation on data stored in a target memory cell in the plurality of memory cells for k times in response to the read command, to obtain k read data of the data in the target memory cell, wherein k is an odd number greater than or equal to 3; and determining, by the peripheral circuit, a read result of the data in the target memory cell according to the k read data.

According to another aspect of the present disclosure, a memory is provided, wherein the memory comprises: a memory array comprising a plurality of memory cells; a plurality of word lines respectively coupled to rows of the memory array; a plurality of bit lines respectively coupled to memory strings of the memory array; and a peripheral circuit coupled to the memory array through the word lines and the bit lines and configured to: receive a read command; perform a read operation on data stored in a target memory cell in the plurality of memory cells for k times in response to the read command, to obtain k read data of the data in the target memory cell, wherein k is an odd number greater than or equal to 3; and determine a read result of the data in the target memory cell according to the k read data.

According to still another aspect of the present disclosure, a memory system is provided, wherein the memory system comprises a memory and a memory controller coupled to the memory; wherein the memory comprises: a memory array comprising a plurality of memory cells; a plurality of word lines respectively coupled to rows of the memory array; a plurality of bit lines respectively coupled to memory strings of the memory array; and a peripheral circuit coupled to the memory array through the word lines and the bit lines and configured to: receive a read command from the memory controller; perform a read operation on data stored in a target memory cell in the plurality of memory cells for k times in response to the read command, to obtain k read data of the data in the target memory cell, wherein k is an odd number greater than or equal to 3; and determine a read result of the data in the target memory cell according to the k read data; and wherein the memory controller is configured to receive the read result of the data in the target memory cell from the memory.

According to still another aspect of the present disclosure, a computer-readable memory medium is provided, wherein the computer-readable memory medium has computer-executable instructions stored thereon that, when executed by a processor, implement any of the methods described above

Example implementations of the present disclosure are shown and described in detail above. It should be understood that the present disclosure is not limited to the detailed structures, arrangements, or implementation methods described herein; rather, the present disclosure is intended to cover various modifications and equivalent arrangements comprised within the spirit and scope of the appended claims.

What is claimed is:

1. A method comprising:
receiving, by a peripheral circuit, a read command;
performing, by the peripheral circuit, a read operation on data stored in a target memory cell in a plurality of memory cells of memory for k times in response to the read command to obtain k read data of the data in the target memory cell, wherein k is an odd number greater than or equal to 3; and
determining, by the peripheral circuit, a read result of the data in the target memory cell based on the k read data.

2. The method of claim 1, wherein:
a word line coupled to the target memory cell is a target word line;
the data stored in the target memory cell comprises M bits;
M is a real number greater than 1;
the peripheral circuit comprises a control logic circuit;
the performing, by the peripheral circuit, of the read operation on the data stored in the target memory cell in the plurality of memory cells for the k times in response to the read command to obtain the k read data of the data in the target memory cell comprises:
applying, by the control logic circuit, an m-th read voltage to the target word line for the k times in response to the read command to perform the read operation on an m-th bit data in M bits of the data stored in the target memory cell for the k times and to obtain k read data of the m-th bit data stored in the target memory cell, wherein m is a real number greater than or equal to 1 and less than or equal to M; and
the determining, by the peripheral circuit, the read result of the data in the target memory cell based on the k read data comprises:
determining, by the control logic circuit, the read result of the m-th bit data in the M bits of the data stored in the target memory cell based on the k read data of the m-th bit data stored in the target memory cell.

3. The method of claim 2, wherein the m-th read voltage comprises at least two different read voltages.

4. The method of claim 2, wherein the determining, by the control logic circuit, of the read result of the m-th bit data in the M bits of the data stored in the target memory cell based on the k read data of the m-th bit data stored in the target memory cell comprises:
if there are
$$\frac{k + 1}{2}$$
or more read data in the k read data of the m-th bit data stored in the target memory cell being a first value, determining the read result of the m-th bit data in the M bits of the data stored in the target memory cell as the first value; and
if there are
$$\frac{k + 1}{2}$$
or more read data in the k read data of the m-th bit data stored in the target memory cell being a second value, determining the read result of the m-th bit data in the M bits of the data stored in the target memory cell as the second value.

5. The method of claim 2, wherein:
k=3;
a bit line coupled to the target memory cell is a target bit line;
the peripheral circuit further comprises a plurality of page buffers;
one of the plurality of page buffers is coupled to one bit line;
a page buffer coupled to the target bit line comprises a latch circuit and a logic operation circuit;
the determining, by the control logic circuit, of the read result of the m-th bit data in the M bits of the data stored in the target memory cell based on the k read data of the m-th bit data stored in the target memory cell comprises:
controlling, by the control logic circuit, the latch circuit in the page buffer coupled to the target bit line to store the k read data of the m-th bit data in the target memory cell;
performing, by the logic operation circuit, a logic operation on the k read data of the m-th bit data stored in the latch circuit to obtain a logic operation result;
storing the logic operation result into the latch circuit; and
obtaining the read result of the m-th bit data based on the logic operation result in the latch circuit.

6. The method of claim 5, wherein:
k=3;
the latch circuit comprises a first latch circuit, a second latch circuit, a third latch circuit, and a fourth latch circuit;
first read data, second read data, and third read data of the m-th bit data are stored into corresponding ones of the first latch circuit, the second latch circuit, and the third latch circuit;
the performing, by the logic operation circuit, of the logic operation on the k read data of the m-th bit data stored in the latch circuit to obtain the logic operation result, and storing the logic operation result into the latch circuit comprises:
performing a logic AND operation on the first read data in the first latch circuit and the second read data in the second latch circuit to obtain a first AND result;
storing the first AND result into the fourth latch circuit;
performing a logic AND operation on the first read data in the first latch circuit and a third read data in the third latch circuit to obtain a second AND result;
storing the second AND result into the first latch circuit;
performing a logic AND operation on the second read data in the second latch circuit and the third read data in the third latch circuit to obtain a third AND result; and
storing the third AND result into the second latch circuit or the third latch circuit;
the logic operation result comprises the first AND result, the second AND result, and the third AND result; and
the obtaining of the read result of the m-th bit data based on the logic operation result in the latch circuit comprises:
performing a logic OR operation on the first AND result in the fourth latch circuit, the second AND result in the first latch circuit, and the third AND result in the second latch circuit or the third latch circuit to obtain the read result of the m-th bit data in the M bits of the data stored in the target memory cell.

7. The method of claim 6, wherein the first to fourth latch circuits multiplex four of a sense latch, a bit line latch, a cache latch, a first data latch, a second data latch, and a third data latch in a page buffer coupled to the target bit line, the method further comprises:
storing the read result of the m-th bit data into the cache latch.

8. The method of claim 2, wherein:
M=4.5;
the target memory cell has any one of 23 memory states; and
the 4.5 bit data stored in the target memory cell is distinguished to belong to any one of the 23 memory states through 22 different read voltages.

9. The method of claim 1, further comprising:
receiving, by the peripheral circuit, address information; and
determining, by the peripheral circuit, the target memory cell from the plurality of memory cells based on the address information.

10. The method of claim 1, wherein the memory comprises NAND memory.

11. A memory comprising:
a memory array comprising a plurality of memory cells;
a plurality of word lines respectively coupled to rows of the memory array;
a plurality of bit lines respectively coupled to memory strings of the memory array; and
a peripheral circuit coupled to the memory array through the word lines and the bit lines and configured to:
receive a read command;
perform a read operation on data stored in a target memory cell in the plurality of memory cells for k times in response to the read command to obtain k read data of the data in the target memory cell, wherein k is an odd number greater than or equal to 3; and
determine a read result of the data in the target memory cell based on the k read data.

12. The memory of claim 11, wherein:
a word line coupled to the target memory cell is a target word line;
the data stored in the target memory cell comprises M bits;
M is a real number greater than 1; and
the peripheral circuit comprises:
a control logic circuit configured to: apply an m-th read voltage to the target word line for the k times in response to the read command, perform the read operation on an m-th bit data in the M bits of the data stored in the target memory cell for the k times, and obtain k read data of the m-th bit data stored in the target memory cell, wherein m is a real number greater than or equal to 1 and less than or equal to M; and
a plurality of page buffers respectively coupled to the plurality of bit lines, wherein a page buffer coupled to a target bit line comprises a latch circuit and a logic operation circuit and is configured to: determine, by the latch circuit and the logic operation circuit, a read result of the m-th bit data in the M bits of the data stored in the target memory cell according to the k read data of the m-th bit data.

13. The memory of claim 12, wherein the peripheral circuit further comprises a voltage generator, the voltage generator configured to:
generate the m-th read voltage for the k times under control of the control logic circuit; and
sequentially apply the m-th read voltage generated for k times to the target word line.

14. The memory of claim 13, wherein:
M=4.5;
the voltage generator is configured to generate 22 different read voltages under the control of the control logic circuit; and
the m-th read voltage applied to the target word line comprises at least two different read voltages of the 22 different read voltages.

15. The memory of claim 12, wherein:
the latch circuit is configured to store the k read data of the m-th bit data in the target memory cell; and
the logic operation circuit is configured to:
perform a logic operation on the k read data of the m-th bit data stored in the latch circuit to obtain a logic operation result;
store the logic operation result into the latch circuit;
obtain a read result of the m-th bit data based on the logic operation result in the latch circuit; and
store the read result of the m-th bit data into the latch circuit.

16. The memory of claim 15, wherein:
k=3;
the latch circuit comprises a first latch circuit, a second latch circuit, a third latch circuit, and a fourth latch circuit;
first read data, second read data, and third read data of the m-th bit data are stored into corresponding ones of the first latch circuit, the second latch circuit, and the third latch circuit;
the logic operation circuit comprises a first AND gate, a second AND gate, a third AND gate, and an OR gate;
the first AND gate is configured to: use the first read data in the first latch circuit as a first input and the second read data in the second latch circuit as a second input to obtain a first AND result, and store the first AND result into the fourth latch circuit;
the second AND gate is configured to: use the first read data in the first latch circuit as the first input and the third read data in the third latch circuit as the second input to obtain a second AND result, and store the second AND result into the first latch circuit;
the third AND gate is configured to: use the second read data in the second latch circuit as the first input and the third read data in the third latch circuit as the second input to obtain a third AND result, and store the third AND result into the second latch circuit or the third latch circuit, wherein the logic operation result comprises the first AND result, the second AND result, and the third AND result; and
the OR gate is configured to: use the first AND result in the fourth latch circuit as its first input, use the second AND result in the first latch circuit as its second input, and use the third AND result in the second latch circuit or the third latch circuit as its third input to obtain the read result of the m-th bit data in the M bits of the data stored in the target memory cell.

17. The memory of claim 16, wherein:
the latch circuit further comprises a cache latch;
an output terminal of the OR gate is coupled to an input terminal of the cache latch; and
the cache latch is configured to receive and store the read result of the m-th bit data from the output terminal of the OR gate.

18. The memory of claim 12, wherein:
M=4.5;
the target memory cell has any one of 23 memory states; and
the 4.5 bit data stored in the target memory cell is distinguished to belong to any one of the 23 memory states through 22 different read voltages.

19. The memory of claim 11, wherein the memory comprises NAND memory.

20. A memory system comprising:
memory; and
a memory controller coupled to the memory;
wherein the memory comprises:
a memory array comprising a plurality of memory cells;
a plurality of word lines respectively coupled to rows of the memory array;
a plurality of bit lines respectively coupled to memory strings of the memory array; and
a peripheral circuit coupled to the memory array through the word lines and the bit lines, the peripheral circuit configured to:
receive a read command from the memory controller;
perform a read operation on data stored in a target memory cell in the plurality of memory cells for k times in response to the read command to obtain k read data of the data in the target memory cell, wherein k is an odd number greater than or equal to 3; and
determine a read result of the data in the target memory cell based on the k read data, wherein the memory controller is configured to receive the read result of the data in the target memory cell from the memory.
